(19) United States
(12) Patent Application Publication
(10) Pub. No.: US 2026/0322019 A1
(43) Pub. Date: Oct. 15, 2026

(54) PLATED LAYER WITH SUPER WEAR RESISTANCE AND HIGH ELECTRICAL CONTACT RELIABILITY, PREPARATION METHOD THEREOF AND TERMINAL WITH THE SAME

(71) Applicant: NINGBO CIRCUIT DEPOSITION TECHNOLOGY CO., LTD, Ningbo (CN)

(72) Inventors: Yingwei ZHUANG, Shanghai (CN); Yinan WANG, Nanjing (CN)

(21) Appl. No.: 19/336,777

(22) Filed: Sep. 23, 2025

(30) Foreign Application Priority Data
Apr. 9, 2025 (CN) 202510437645.X

(51) Int. Cl. H01R 13/03; H01H 1/021; H01H 11/04; H01R 43/16

(52) U.S. Cl. CPC H01R 13/03; H01H 1/021; H01H 11/041; H01R 43/16; H01H 2011/046

(57) ABSTRACT

A plated layer with super wear resistance and high electrical contact reliability plated on a workpiece substrate, including a hard bottom plated layer, a hard precious metal layer and a lubricating layer which are sequentially arranged on the workpiece substrate, and the lubricating layer includes a pure gold solid lubricating layer and an organic liquid lubricating layer. The plated layer according to the present application is of a multilayer composite structure, and the hard bottom plated layer can avoid a failure of the plated layer due to wear during repeated plugging and unplugging; the hard precious metal layer can ensure that the terminal has good electrical contact stability; the pure gold solid lubricating layer can be fitted with contact of hard precious metal, so that conductive stability thereof is improved; the organic liquid lubricating layer can improve abnormal wear in an initial period of plugging and unplugging.

### CROSS-REFERENCE TO RELATED APPLICATION

The present application claims the priority and benefit of Chinese patent application No. 202510437645.X, filed on Apr. 9, 2025. The entirety of Chinese patent application No. 202510437645.X is hereby incorporated by reference herein and made a part of this specification.

### TECHNICAL FIELD

The present application relates to the field of electronic components, and in particular, to a plated layer with super wear resistance and high electrical contact reliability, a preparation method thereof and a terminal with the same.

### BACKGROUND ART

A metal part for an electrical connection common in the market is usually a copper alloy or stainless steel terminal with a surface plated with nickel and hard gold plated layers, and the nickel plated layer is used as a bottom plated layer to play isolation and support roles, so as to prevent mutual permeation between the hard gold plated layer and base metal and corrosion of an environmental medium, and meanwhile avoid that the electrical connection fails due to rapid wearing in a mechanical friction process. However, when the contact metal is applied to a connector or switch plugged and unplugged at a high frequency, since the nickel plated layer has insufficient hardness, and the surface hard gold plated layer does not have a self-lubricating function, the wear failure is still a major problem in the industry.

US patent No. U.S. Pat. No. 12,362,510B2 discloses a contact component, a connector, a composition and a method for producing the contact component, which aim at achieving the object of reducing a friction coefficient during electrical contact and maintaining a good electrical contact performance at a low contact force, in particular by coating a surface of a metal substrate with an organic film and incorporating the same kind of metal particles in the organic film to realize a balance of low resistance and sliding durability. However, the solution of this patent does not solve the problem that during thousands of times of consecutive plugging and unplugging or switching of the terminal, the hardness of the substrate metal is insufficient, so that the integral plated layer is rapidly worn through.

Chinese patent No. CN110983333A discloses a neodymium iron boron composite plated layer, including a neodymium iron boron substrate layer, at least one water-plated layer located on an upper surface of the neodymium iron boron substrate layer and at least one PVD vacuum-plated layer located on an upper surface of the water-plated layer, wherein in the neodymium iron boron composite plated layer, with a synergistic effect of an electroplated layer and the PVD vacuum-plated layer, holes in two different plated species are staggered, porosity is reduced, density of the neodymium iron boron composite plated layer is improved, hardness is high, and wear resistance and corrosion resistance of the neodymium iron boron composite plated layer are improved. However, the plated layer has no self-lubricating effect and has a large friction coefficient, and if the plated layer is used as a connector terminal plated layer, the metal plated layer is worn through after less than five thousand times of friction switching. Moreover, the plated layer has a high surface resistance value, so that the plated layer is not suitable for the field of electronic connectors mainly involving signal transmission.

### SUMMARY

In order to improve the problems of poor wear resistance of a plated layer and an electrical contact failure of an existing terminal, the present application provides a plated layer with super wear resistance and high electrical contact reliability, a preparation method thereof and a terminal with the same.

In a first aspect, the present application provides a plated layer with super wear resistance and high electrical contact reliability, which adopts the following technical solution.

A plated layer with super wear resistance and high electrical contact reliability plated on a workpiece substrate, including a hard bottom plated layer, a hard precious metal layer and a lubricating layer which are sequentially arranged on the workpiece substrate, wherein the lubricating layer includes a pure gold solid lubricating layer and an organic liquid lubricating layer, the pure gold solid lubricating layer is made of a pure gold material with purity of more than 99.99%, and a thickness of the pure gold solid lubricating layer is 0.05-1 μm.

Optionally, the thickness of the pure gold solid lubricating layer is 0.1-0.5 μm.

Here, it should be particularly noted that the thickness of the pure gold solid lubricating layer can be adjusted according to a specific contact manner of a terminal. Specifically, when the terminal is used as a microswitch terminal, the thickness of the pure gold solid lubricating layer can be 0.1-0.2 μm due to small sliding friction in a fitting process; when the terminal is used as a connector terminal mainly involving plugging and unplugging, since the fitting process mainly involves sliding friction, the thickness of the pure gold solid lubricating layer can be 0.2-0.5 μm.

If the thickness is not within the above range, when the thickness of the pure gold solid lubricating layer is too low, repeated plugging and unplugging are prone to accelerate wear of the hard precious metal layer, and when the thickness of the pure gold solid lubricating layer is too high, local accumulation of “gold mud” is prone to occur, or there is a slight adhesion phenomenon.

Optionally, the hard bottom plated layer has hardness superior to that of nickel.

Optionally, the hard bottom plated layer is made of any one of chromium, titanium, tungsten, titanium-tungsten alloy, nickel-chromium alloy, nickel-phosphorus alloy and nickel-tungsten alloy.

Optionally, a thickness of the hard bottom plated layer is 0.5-10 μm.

Optionally, the thickness of the hard bottom plated layer is 2-6 μm.

Optionally, the hard precious metal layer is made of any one of rhodium, iridium, nickel-containing hard gold and cobalt-containing hard gold.

When the hard precious metal layer is made of the nickel-containing hard gold or the cobalt-containing hard gold, nickel or cobalt contained therein is used as a hard gold hardening element, and a mass of the nickel or the cobalt accounts for 0.1%-1% of that of the nickel-containing hard gold or the cobalt-containing hard gold.

Optionally, a thickness of the hard precious metal layer is 0.2-6 μm.

Optionally, the thickness of the hard precious metal layer is 0.5-4 μm.

Optionally, the organic liquid lubricating layer is a coating film formed of an organic substance.

Optionally, the organic liquid lubricating layer is a coating film formed of thiol, azole, fluorohydrocarbon containing polar groups, or the like.

Optionally, the organic liquid lubricating layer is a coating film formed of alkylthiol, azole and fluorohydrocarbon containing polar groups.

Optionally, a thickness of the organic liquid lubricating layer is 0.2-2 μm.

Optionally, the workpiece substrate is made of copper alloy or nickel alloy.

In a second aspect, the present application provides a method for preparing the plated layer with super wear resistance and high electrical contact reliability, which adopts the following technical solution.

A method for preparing the plated layer with super wear resistance and high electrical contact reliability, including steps of sequentially obtaining the hard bottom plated layer, the hard precious metal layer, the pure gold solid lubricating layer and the organic liquid lubricating layer on the workpiece substrate.

Optionally, the method further includes a step of controlling a value of surface roughness Ra of the hard precious metal layer to b μm, wherein the thickness of the pure gold solid lubricating layer is set to a μm, and a difference between b and a ranges from 0 to 0.1.

In a preparation process of the plated layer, the surface roughness of the hard precious metal layer can be properly adjusted according to a thickness requirement of the pure gold solid lubricating layer. For example, a surface of the substrate can be adjusted by adopting sand blasting and thread rolling or surface appearances of the hard bottom plated layer and the hard precious metal layer can be further adjusted by adopting an electroplating manner, so that the pure gold solid lubricating layer covering the hard precious metal layer can exert an optimal wear resisting effect, and a resistance value can be stabilized at a quite low level.

In a third aspect, the present application provides a terminal, which adopts the following technical solution.

A terminal including the workpiece substrate and the plated layer plated on the workpiece substrate.

The terminal according to the present application has a low resistance value and a long service life.

In summary, the present application has the following beneficial effects.

The plated layer according to the present application is of a multilayer composite structure, and the hard bottom plated layer has a hardness advantage compared with a conventional nickel layer, and can avoid a failure of the plated layer due to wear during repeated plugging and unplugging; the hard precious metal layer has excellent wear resistance and a conductive function, and can ensure that the terminal has good electrical contact stability; the pure gold solid lubricating layer can be fitted with contact of hard precious metal, so that conductive stability thereof is improved, and a self-lubricating function is formed to effectively reduce wear; the organic liquid lubricating layer can improve abnormal wear in an initial period of plugging and unplugging to achieve a better running-in effect.

Specifically, the pure gold solid lubricating layer is made from the pure gold material, which plays a key role in relieving the wear of the hard precious metal layer and maintaining low impedance stability, and the pure gold material has ideal conductivity and also has obvious advantages in chemical stability and high temperature resistance.

### BRIEF DESCRIPTION OF THE DRAWINGS

FIG. 1 is a schematic structural diagram of a plated layer with super wear resistance and high electrical contact reliability on a terminal according to an embodiment of the present application;

FIG. 2 is a surface appearance view (magnified 300 times) of a high frequency switch terminal sample of Example 1 after 5,000 times of plugging and unplugging tests; and

FIG. 3 is a surface appearance view (magnified 300 times) of a high frequency switch terminal sample of Example 5 after 5,000 times of plugging and unplugging tests.

### DETAILED DESCRIPTION

The technical solutions in the embodiments of the present invention are clearly and completely described with reference to the embodiments of the present invention and the accompanying drawings. Apparently, the described embodiments are not all but only a part of the embodiments of the present invention.

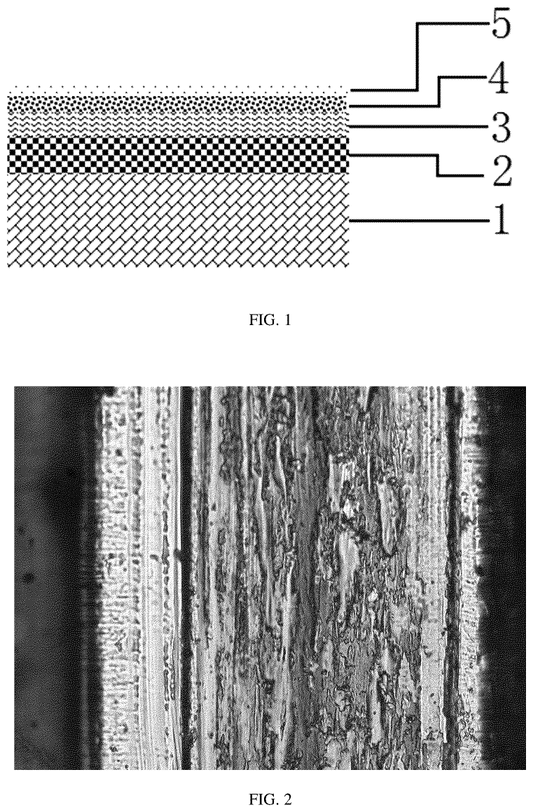

As shown in FIG. 1, an embodiment of the present application provides a plated layer with super wear resistance and high electrical contact reliability, including a hard bottom plated layer, a hard precious metal layer, a pure gold solid lubricating layer and an organic liquid lubricating layer which are sequentially plated on a workpiece substrate.

An embodiment of the present application further provides a method for preparing the plated layer with super wear resistance and high electrical contact reliability, which generally includes the following steps:
step A: performing electrolytic degreasing and activation on the workpiece substrate;
step B: obtaining the hard bottom plated layer on a surface of the workpiece substrate;
step C: obtaining the hard precious metal layer on a surface of the hard bottom plated layer of the workpiece substrate;
step D: obtaining the pure gold solid lubricating layer on a surface of the hard precious metal layer of the workpiece substrate; and
step E: obtaining the organic liquid lubricating layer on a surface of the pure gold solid lubricating layer of the workpiece substrate.

Specifically, the hard bottom plated layer, the hard precious metal layer and the pure gold solid lubricating layer can be obtained layer by layer in sequence in an electroplating manner, and can also be obtained layer by layer in sequence in a PVD sputtering manner.

When the hard bottom plated layer (taking nickel tungsten alloy as an example), the hard precious metal layer (taking cobalt-containing hard gold as an example, a cobalt content in the cobalt-containing hard gold is 0.5 wt %) and the pure gold solid lubricating layer (taking a pure gold layer as an example) are obtained in the electroplating manner, the method completely includes the following steps:
step S1: immersing a workpiece (copper alloy C51100 elastic piece crimping terminal) to be used in a degreasing agent solution for electrolytic degreasing to obtain a degreased workpiece, a temperature of the degreasing agent solution being 65° C., a current being 3 A/dm², and a time being 2 min; and then taking out the degreased workpiece and rinsing the degreased workpiece through multi-stage rinsing to ensure that a residual degreasing agent on a surface of the degreased workpiece is fully removed, a time for each time of rinsing being 2 min;
step S2: immersing a rinsed workpiece obtained in the step S1 into a dilute sulfuric acid solution with a volume fraction of 25% for activation to remove a surface metal oxide layer, then taking out an activated workpiece and rinsing the activated workpiece through multi-stage rinsing to remove residual acid on a surface of the activated workpiece, a time for each time of rinsing being 2 min;
step S3: immersing a rinsed workpiece obtained in the step S2 into a nickel tungsten electroplating solution to electroplate a hard nickel tungsten alloy plated layer, wherein the nickel tungsten electroplating solution includes: 250 g/L of nickel sulfate or nickel sulfamate, 60 g/L of sodium tungstate, ammonium tungstate or metatungstate, 40 g/L of boric acid, 40 g/L of organic complex acid salt, and 0.1 g/L of saccharin sodium dihydrate; a pH value of the nickel tungsten electroplating solution is 2.6, a temperature of the plating solution is 70° C., a current density is 2 ASD, and a time is 20 min; taking out the workpiece plated with the hard nickel tungsten alloy plated layer after electroplating, and rinsing the workpiece through multi-stage rinsing to removing a residual plating solution on a surface of the workpiece plated with the hard nickel tungsten alloy plated layer, a time for each time of rinsing being 2 min;
step S4: immersing a rinsed workpiece obtained in the step S2 into a hard gold electroplating solution to electroplate a cobalt-containing hard gold layer; wherein the hard gold electroplating solution includes: 10 g/L of potassium aurous cyanide, 2.5 g/L of cobalt sulfate, 110 g/L of citric acid, and 140 g/L of potassium citrate; a pH value of the hard gold electroplating solution is 5.0, a temperature is 60° C., a current density is 1 ASD, and a time is 20 min; taking out the workpiece plated with the cobalt-containing hard gold layer after electroplating, and rinsing the workpiece through multi-stage rinsing to remove the residual plating solution on a surface of the workpiece plated with the cobalt-containing hard gold layer, a time for each time of rinsing being 2 min;
step S5: immersing a rinsed workpiece obtained in the step S4 into a pure gold electroplating solution to electroplate the pure gold lubricating layer; wherein the pure gold electroplating solution includes: 10 g/L of potassium aurous cyanide, 0.015 g/L of thallium sulfate, 80 g/L of citric acid, and 120 g/L of potassium citrate; a pH value of the pure gold electroplating solution is 4.4, a temperature is 70° C., a current density is 0.8 ASD, and a time is 8 min; taking out the workpiece plated with the pure gold lubricating layer after electroplating, and rinsing the workpiece through multi-stage rinsing to remove the residual plating solution on a surface of the workpiece plated with the pure gold lubricating layer, a time for each time of rinsing being 2 min;
step S6: taking out a rinsed workpiece obtained in the step S5, and immersing the rinsed workpiece into an aqueous solution containing an organic solute to obtain the organic liquid lubricating layer; wherein the aqueous solution containing the organic solute includes: 20 g/L of octadecyl mercaptan, 5 g/L of benzotriazole and 5 g/L of polyethylene glycol, a temperature is 60° C., and a time is 1 min; then taking out the workpiece with the organic liquid lubricating layer, and rinsing the workpiece through multi-stage rinsing to remove a residual solution on a surface of the workpiece with the organic liquid lubricating layer, a time for each time of rinsing being 2 min; and
step S7: taking out a rinsed workpiece obtained in the step S6, putting the rinsed workpiece into a drying oven, and drying moisture on the surface of the workpiece by hot air at a temperature of 80° C. for 5 min, and finally obtaining the plated layer with super wear resistance and high electrical contact reliability on the workpiece substrate.

When the hard bottom plated layer (taking titanium tungsten alloy as an example), the hard precious metal layer (taking iridium metal as an example) and the pure gold solid lubricating layer (taking a pure gold layer as an example) are obtained in the PVD sputtering manner, the method completely includes the following steps:
step S1: immersing a workpiece (copper alloy C51100 elastic piece crimping terminal) to be used in a degreasing agent solution for electrolytic degreasing to obtain a degreased workpiece, a temperature of the degreasing agent solution being 65° C., a current being 3 A/dm², and a time being 2 min; and then taking out the degreased workpiece and rinsing the degreased workpiece through multi-stage rinsing to ensure that a residual degreasing agent on a surface of the workpiece is fully removed, a time for each time of rinsing being 2 min;
step S2: immersing a rinsed workpiece obtained in the step S1 into a dilute sulfuric acid solution with a volume fraction of 25% for activation to remove a surface metal oxide layer, then taking out an activated workpiece and rinsing the activated workpiece through multi-stage rinsing to remove residual acid on a surface of the activated workpiece, a time for each time of rinsing being 2 min;
step S3: putting a rinsed workpiece obtained in the step S2 into a drying oven, and evaporating moisture on the surface of the workpiece through hot air circulation to obtain a dried workpiece, a drying temperature being 110° C., and a drying time being 10 min;
step S4: putting the dried workpiece into a vacuum chamber, performing plasma cleaning on the dried workpiece to ensure cleanness of a surface of a plated body, and controlling a hydrogen partial pressure to be 0.2 MPa, power to be 200 W and a time to be 5 min;
step S5: putting a cleaned workpiece obtained in the step S4 into a vacuum sputtering apparatus, sputtering titanium tungsten alloy, controlling a working pressure to be 0.2 Pa, adopting argon as sputtering gas, and adopting a titanium tungsten alloy target, a sputtering current being 1 A/dm², a voltage being 170V, and a time being 10 min;
step S6: sputtering an iridium metal layer, controlling a working pressure to be 0.2 Pa, adopting argon as sputtering gas, and adopting an iridium target, a sputtering current being 1 A/dm², a voltage being 170V, and a time being 200 min;
step S7: sputtering the pure gold layer, controlling a working pressure to be 0.2 Pa, adopting argon as sputtering gas, and adopting a gold target, a sputtering current being 1 A/dm², a voltage being 170V, and a time being 10 min;
step S8: putting a sputtered workpiece obtained in the step S7 into a film coating solvent for 20 s at normal temperature, an oily film coating solution (film coating solvent) being compounded by 3 w % of cutting oil and 97 w % of volatile solvents; and
step S9: taking out a film-coated workpiece obtained in the step S7, putting the film-coated workpiece into a drying oven, and drying moisture on the surface of the workpiece by hot air at a temperature of 100° C. for 5 min, and finally obtaining the plated layer with super wear resistance and high electrical contact reliability on the workpiece substrate.

Compared with the PVD sputtering manner, the electroplating manner can generate the uniform plated layer on the surface of the workpiece with a complex shape, metal ions are uniformly deposited under the action of an electric field, deep holes and grooves can be well covered, a sputtering shadow region is prone to be generated by PVD sputtering due to a movement track of particles, and the PVD sputtering is inferior in this respect. In addition, the electroplating manner is excellent in control of a thickness of the plated layer, and can easily realize deposition of plated layers with thicknesses from several microns to dozens of microns only by adjusting parameters according to requirements, the PVD sputtering is more suitable for preparing thin plated layers below a micron level, and an efficiency is low. However, the PVD sputtering can produce metal, such as titanium, zirconium and tungsten, which is difficult to deposit from aqueous solutions, and can form metal layers on surfaces of various non-conductor materials.

The solution of the present application is further explained below using specific examples and comparative examples. It should be noted that, in the following examples and comparative examples, the copper alloy C51100 elastic piece crimping terminal is used as the workpiece substrate, and the hard bottom plated layer, the hard precious metal layer and the pure gold solid lubricating layer are obtained by electroplating according to the aforementioned complete electroplating steps, thus preparing a high frequency switch terminal sample.

Example 1: Pure nickel was electroplated on the surface of the workpiece substrate as the hard bottom plated layer with a thickness of 3 μm; and then cobalt-containing hard gold (cobalt content: 0.5 wt %) was electroplated on the surface of the hard bottom plated layer as the hard precious metal layer with a thickness of 2 μm.

Example 2: Nickel tungsten alloy was electroplated on the surface of the workpiece substrate as the hard bottom plated layer with a thickness of 3 μm; and then cobalt-containing hard gold (cobalt content: 0.5 wt %) was electroplated on the surface of the hard bottom plated layer as the hard precious metal layer with a thickness of 2 μm.

Example 3: Pure nickel was electroplated on the surface of the workpiece substrate as the hard bottom plated layer with a thickness of 3 μm; and then cobalt-containing hard gold (cobalt content: 0.5 wt %) was electroplated on the surface of the hard bottom plated layer as the hard precious metal layer with a thickness of 2 μm; and finally the organic liquid lubricating layer was formed on the surface of the hard precious metal layer with a thickness of 0.5 μm.

Example 4: Nickel tungsten alloy was electroplated on the surface of the workpiece substrate as the hard bottom plated layer with a thickness of 3 μm; and then cobalt-containing hard gold (cobalt content: 0.5 wt %) was electroplated on the surface of the hard bottom plated layer as the hard precious metal layer with a thickness of 2 μm; and finally the organic liquid lubricating layer was formed on the surface of the hard precious metal layer with a thickness of 0.5 μm.

Example 5: Nickel tungsten alloy was electroplated on the surface of the workpiece substrate as the hard bottom plated layer with a thickness of 3 μm; and then cobalt-containing hard gold (cobalt content: 0.5 wt. %) was electroplated on the surface of the hard bottom plated layer as the hard precious metal layer with a thickness of 2 μm; then the pure gold lubricating layer was electroplated on the surface of the hard precious metal layer with a thickness of 0.15 μm; and finally the organic liquid lubricating layer was formed on the surface of the pure gold lubricating layer with a thickness of 0.5 μm.

All preparation steps and corresponding parameters of the Examples 1-5 are kept consistent, unless stated otherwise.

In order to evaluate contact reliability of the high frequency switch terminal samples prepared in the above examples under a sliding condition, resistance values and cycle numbers thereof were tested. Based on IEC 60512-2 and IEC60512-5, a constant contact pressure of 0.31±0.03N was applied, a reciprocating sliding stroke of 0.74±0.06 mm of the switch terminal was driven and simulated, and meanwhile, a change of contact resistance was monitored in real time with a four-terminal method. An alternating current with a maximum value of 100 mA and a voltage with a maximum value of 20 mV were adopted for a test load. When an instantaneous jump of the resistance value exceeded a threshold of 50 mΩ, it was judged that a failure occurred, and a failure cycle number was recorded. The sample of each example was repeatedly tested 5 times, results of the 5 tests were averaged to obtain a result for the corresponding example sample, and specific results were shown in table 1.

TABLE 1
Sliding test results

| | Resistance value/mΩ | | Failure cycle number |
|---|---|---|---|
| Example 1 | 6.45 | mΩ | 691 |
| Example 2 | 6.34 | mΩ | 2,218 |
| Example 3 | 8.43 | mΩ | 3,452 |
| Example 4 | 8.21 | mΩ | 84,531 |
| Example 5 | 2.98 | mΩ | 556,743 |

As can be seen from the results in table 1, a wear alleviating effect of the organic liquid lubricating layer on the hard bottom plated layer of the sample is obvious, and the pure gold lubricating layer not only can further alleviate wear, but also can reduce the resistance value and stabilize it at a low level. Therefore, when the plated layer according to the present application is applied to the high frequency switch terminal, an aging life thereof can reach more than half million.

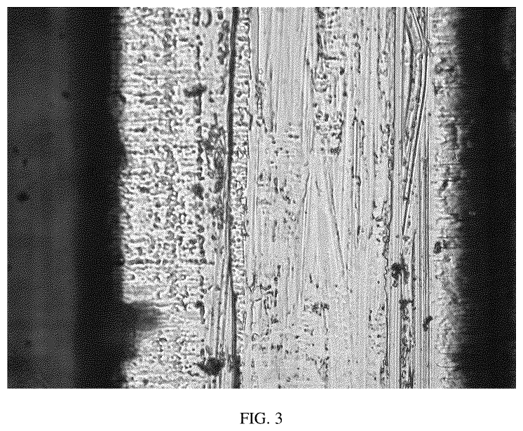

A plugging and unplugging scene of an HDMI terminal was simulated for the high frequency switch terminal samples prepared in the Example 1 and Example 5. 5,000 times of plugging and unplugging tests were respectively performed, and surface wear conditions were observed. FIG. 2 is a surface appearance view (magnified 300 times) of the high frequency switch terminal sample of the Example 1 after 5,000 times of plugging and unplugging tests; and FIG. 3 is a surface appearance view (magnified 300 times) of the high frequency switch terminal sample of the Example 5 after 5,000 times of plugging and unplugging tests. As can be seen from a comparison between FIG. 2 and FIG. 3, after 5,000 times of plugging and unplugging tests, a surface of the high frequency switch terminal of the Example 1 has obvious wear traces, the surface of the plated layer is rough, and dense scratches, peeling regions and dark oxidation/corrosion spots can be seen; after 5,000 times of plugging and unplugging tests, an overall state of the high frequency switch terminal of the Example 5 is obviously superior to that of the Example 1, the surface of the plated layer is relatively smooth, scratches are shallow and have sparse distribution, and no obvious oxidation or corrosion signs exist. Therefore, in the present application, by plating the surface of the hard precious metal layer with the pure gold solid lubricating layer and the organic liquid lubricating layer, a plugging and unplugging wear resisting capacity of the high frequency switch terminal is remarkably improved, and the high frequency switch terminal has a more reliable performance in a long-term high frequency use scene.

It should be noted that, herein, the term “comprising”, “including”, or any other variant thereof is intended to encompass a non-exclusive inclusion, so that the process, method, article or device including a series of elements does not only include those elements, but also includes other elements not explicitly listed, or further includes inherent elements of the process, method, article or device.

Although the embodiments of the present invention have been shown and described, all other embodiments obtained by a person of ordinary skill in the art without creative efforts shall fall within the protection scope of the present invention. It may be appreciated by those skilled in the art that various changes, modifications, substitutions and alterations can be made in these embodiments without departing from the principles and spirit of the invention, the scope of which is defined in the appended claims and their equivalents.

The above embodiments are preferred embodiments of the present application, and the protection scope of the present application is not limited thereby, and therefore, equivalent changes made according to the structure, shape and principle of the present application shall be covered by the protection scope of the present application.

### LISTING OF REFERENCE SIGNS

1. Workpiece Substrate;
2. Hard Bottom Plated Layer;
3. Hard Precious Metal Layer;
4. Pure Gold Solid Lubricating Layer;
5. Organic Liquid Lubricating Layer.

What is claimed is:

1. A plated layer with super wear resistance and high electrical contact reliability plated on a workpiece substrate, comprising a hard bottom plated layer, a hard precious metal layer and a lubricating layer which are sequentially arranged on the workpiece substrate, wherein the lubricating layer comprises a pure gold solid lubricating layer and an organic liquid lubricating layer, the pure gold solid lubricating layer is made of a pure gold material with purity of more than 99.99%, and a thickness of the pure gold solid lubricating layer is 0.05-1 μm.

2. The plated layer with super wear resistance and high electrical contact reliability according to claim 1, wherein the hard bottom plated layer is made of any one of chromium, titanium, tungsten, titanium-tungsten alloy, nickel-chromium alloy, nickel-phosphorus alloy or nickel-tungsten alloy.

3. The plated layer with super wear resistance and high electrical contact reliability according to claim 1, wherein a thickness of the hard bottom plated layer is 0.5-10 μm.

4. The plated layer with super wear resistance and high electrical contact reliability according to claim 1, wherein the hard precious metal layer is made of any one of rhodium, iridium, nickel-containing hard gold or cobalt-containing hard gold.

5. The plated layer with super wear resistance and high electrical contact reliability according to claim 1, wherein a thickness of the hard precious metal layer is 0.2-6 μm.

6. The plated layer with super wear resistance and high electrical contact reliability according to claim 1, wherein the organic liquid lubricating layer is a coating film formed of an organic substance.

7. The plated layer with super wear resistance and high electrical contact reliability according to claim 1, wherein a thickness of the organic liquid lubricating layer is 0.2-2 μm.

8. A method for preparing the plated layer with super wear resistance and high electrical contact reliability according to claim 1, comprising steps of sequentially obtaining the hard bottom plated layer, the hard precious metal layer, the pure gold solid lubricating layer and the organic liquid lubricating layer on the workpiece substrate.

9. The method for preparing the plated layer with super wear resistance and high electrical contact reliability according to claim 8, further comprising a step of controlling a value of surface roughness Ra of the hard precious metal layer to b μm, wherein the thickness of the pure gold solid lubricating layer is set to a μm, and a difference between b and a ranges from 0 to 0.1.

10. A terminal comprising the workpiece substrate and the plated layer according to claim 1 plated on the workpiece substrate.
